(19) United States
(12) Patent Application Publication
(10) Pub. No.: US 2022/0259378 A1
(43) Pub. Date: Aug. 18, 2022

(54) RESIN COMPOSITION, PREPREG, METHOD FOR MANUFACTURING PREPREG, LAMINATE, AND PRINTED WIRING BOARD

(71) Applicant: Panasonic Intellectual Property Management Co., Ltd., Osaka (JP)

(72) Inventors: Dai SASAKI, Fukushima (JP); Yohsuke ISHIKAWA, Fukushima (JP); Kazuki MATSUMURA, Fukushima (JP); Yasunori NISHIGUCHI, Osaka (JP); Hiroki TAMIYA, Fukushima (JP); Koji KISHINO, Fukushima (JP)

(73) Assignee: Panasonic Intellectual Property Management Co., Ltd., Osaka (JP)

(21) Appl. No.: 17/622,119

(22) PCT Filed: Jun. 19, 2020
(86) PCT No.: PCT/JP2020/024212

§ 371 Date: Dec. 22, 2021

(30) Foreign Application Priority Data
Jun. 26, 2019 (JP) 2019-119109

(51) Int. Cl. C08G 65/38; C08K 3/011; C08K 9/04; C08J 3/12; C08K 3/013; C08K 5/00; C08J 5/24; H05K 1/03

(52) U.S. Cl. CPC C08G 65/38; C08K 3/011; C08K 9/04; H05K 1/0366; C08K 3/013; C08K 5/0066; C08J 5/24; C08J 3/128

(57) ABSTRACT

A resin composition contains: a modified polyphenylene ether compound (A) having, at one terminal, a group with an unsaturated double bond; a cross-linking agent (B) having a carbon-carbon double bond; a hindered amine-based polymerization inhibitor (C); and a solvent (D).

### TECHNICAL FIELD

The present disclosure generally relates to a resin composition, a prepreg, a method for manufacturing a prepreg, a laminate, and a printed wiring board. More particularly, the present disclosure relates to a resin composition containing a modified polyphenylene ether compound, a prepreg formed out of the resin composition, a method for manufacturing a prepreg using the resin composition, a laminate formed out of the resin composition, and a printed wiring board formed out of the resin composition.

### BACKGROUND ART

Patent Literature 1 teaches forming a prepreg, a laminate, and a printed wiring board out of a polyphenylene ether resin composition containing a modified polyphenylene ether and a thermosetting curing agent.

### CITATION LIST

### Patent Literature

Patent Literature 1: WO 2014/034103 A1

### SUMMARY OF INVENTION

The problem to be overcome by the present disclosure is to provide a resin composition easily applicable to both a roll press method and a batch press method when a laminate or a printed wiring board is manufactured, a prepreg formed out of the resin composition, a method for manufacturing a prepreg using the resin composition, a laminate formed out of the resin composition, and a printed wiring board formed out of the resin composition.

A resin composition according to an aspect of the present disclosure contains: a modified polyphenylene ether compound (A) having, at one terminal, a group with an unsaturated double bond; a cross-linking agent (B) having a carbon-carbon double bond; a hindered amine-based polymerization inhibitor (C); and a solvent (D).

A resin composition according to another aspect of the present disclosure contains: a modified polyphenylene ether compound (A) having, at one terminal, a group with an unsaturated double bond; a cross-linking agent (B) having a carbon-carbon double bond; composite particles (I), each of the composite particles (I) having a core containing a fluororesin and a shell containing a silicon oxide that coats the core; and a solvent (D). The silicon oxide is treated with phenylamino.

A prepreg according to still another aspect of the present disclosure includes a dried or semi-cured product of the resin composition described above.

A method for manufacturing a prepreg according to yet another aspect of the present disclosure includes the steps of: impregnating a base material with the resin composition described above; and heating the resin composition after the step of impregnating. The step of heating satisfies a heating condition expressed by the following mathematical formula (I):

$$4500 ≦ {\sum }_{n = 1}^{i} ( {Tp}_{n} + {Tm}_{n} ) ≦ 10000 \qquad ( 1 )$$

where i indicates the number of process steps having respectively different heating temperatures and included in the step of heating, Tpₙ indicates a heating temperature (° C.) in an n^{th} process step out of the i process steps, and Tmₙ indicates a heating time (sec) in the n^{th} process step out of the i process steps.

A laminate according to yet another aspect of the present disclosure includes an insulating layer containing a cured product of the resin composition described above.

A printed wiring board according to yet another aspect of the present disclosure includes an insulating layer containing a cured product of the resin composition described above.

### DESCRIPTION OF EMBODIMENTS

First, it will be described generally how the present inventors acquired the concept of the present disclosure.

A polyphenylene ether resin composition including a modified polyphenylene ether and a thermosetting curing agent as described in WO 2014/034103 A1 has heat resistance which is good enough to use the resin composition to form an insulating layer with a low dielectric constant and a low dielectric loss tangent.

Methods for manufacturing a laminate are classifiable into a continuous press method in which a material such as a long prepreg or a sheet of metal foil is stacked while being transported and is continuously pressed with a roll press, for example, and a batch press method in which a material such as a prepreg or a sheet of metal foil is stacked and pressed with a heating platen, for example.

The present inventors considered first applying, to the continuous press method, a prepreg formed out of a resin composition containing a modified polyphenylene ether and a thermosetting curing agent and a laminate formed by using the prepreg. Next, the present inventors considered applying such a prepreg and such a laminate to the batch press method.

The continuous press method requires that the prepreg have low resin flowability to make the thickness formed out of the prepreg accurate enough. On the other hand, according to the batch press method, if the prepreg has too low flow resin flowability when the prepreg is stacked over conductor wiring, then gaps between respective portions of the conductor wiring may be insufficiently filled with the insulating layer, thus requiring appropriately adjusting the resin flowability of the prepreg.

To increase the resin flowability of a prepreg, formed out of the resin composition to be applied to the continuous press method, to the point of making the prepreg applicable to the batch press method, the heating temperature of the resin composition may be lowered while the prepreg is being formed.

However, lowering the heating temperature of the resin composition increases the chances of a solvent in the resin composition being left in the prepreg, thus causing an increase in the volume of an organic compound vaporized while a laminate is being manufactured out of the prepreg.

This requires preparing resin compositions with mutually different chemical makeups for a situation where the continuous press method is adopted and for a situation where the batch press method is adopted, thus imposing a burden on the manufacturing process.

Thus, the present inventors carried out extensive research and development to obtain a prepreg that reduces the chances of causing a dispersion in the thickness of the insulating layer when applied to the continuous batch method, facilitates filling the gaps of the conductor wiring with the insulating layer when applied to the batch press method, and reduces the volatile content when heated, and a resin composition to form such a prepreg, thus acquiring the concept of the present disclosure.

Next, an embodiment of the present disclosure will be described.

A resin composition according to an exemplary embodiment (hereinafter referred to as a “composition (X)”) contains: a modified polyphenylene ether compound (A) having, at one terminal, a group with an unsaturated double bond (hereinafter referred to as a “compound (A)”); a cross-linking agent (B) having a carbon-carbon double bond; a hindered amine-based polymerization inhibitor (C); and a solvent (D).

According to this embodiment, when the composition (X) is heated to be dried or semi-cured, the hindered amine-based polymerization inhibitor (C) retards the reaction between the compound (A) and a diene-based curing agent. Thus, even if the composition (X) is heated to vaporize the solvent (D) sufficiently from the composition (X), the reaction between the compound (A) and the diene-based curing agent does not proceed smoothly. This facilitates preventing the resin flowability of the prepreg including a dried or semi-cured product of the composition (X) from becoming too small. This enables easily obtaining a prepreg with appropriately controlled resin flowability while sufficiently reducing the volume of the residual solvent (D). This may reduce the dispersion in the thickness of the insulating layer when the prepreg is applied to the continuous press method, facilitate filling the gaps of the conductor wiring with the insulating layer when the prepreg is applied to the batch press method, and reduce the volatile content when the prepreg is heated.

The composition (X) may contain: the compound (A); the cross-linking agent (B); composite particles (I), each having a core containing a fluororesin and a shell containing a silicon oxide that coats the core; and the solvent (D). The silicon oxide of the composite particles (I) may be treated with phenylamino. In that case, the composition (X) may or may not contain the hindered amine-based polymerization inhibitor (C). The composite particles (I) may lower the coefficient of linear expansion (particularly, the coefficient of linear expansion al at a temperature lower than the glass transition temperature) of the insulating layer formed out of the prepreg and increase the tenacity of the cured product while lowering the dielectric constant of the cured product and increasing the heat resistance and flame retardancy thereof and reducing an increase in the viscosity of the composition (X).

Note that the composite particles (I) may reduce the coefficient of linear expansion of the insulating layer presumably because the composite particles (I) reduce the modulus of elasticity of the cured product. More specifically, as the composite particles (I) reduce the modulus of elasticity of the cured product, the effect of the base material on the coefficient of linear expansion of the insulating layer increases, thus probably causing a decrease in the coefficient of linear expansion of the overall insulating layer.

In addition, the composite particles (I) may also increase the resin flowability of a prepreg formed out of the composition (X). This allows the resin flowability of the prepreg to be adjusted by using the composite particles (I). Thus, this enables easily obtaining a prepreg with appropriately controlled resin flowability while sufficiently reducing the volume of the residual solvent (D). Consequently, this reduces the chances of causing a dispersion in the thickness of the insulating layer when the prepreg is applied to the continuous press method, facilitates filling the gaps between respective portions of the conductor wiring with the insulating layer when the prepreg is applied to the batch press method, and reduces the volatile content when the prepreg is heated. In addition, treating the silicon oxide of the composite particles (I) with phenylamino allows the composite particles (I) to reduce the chances of causing a decrease in peel strength between the insulating layer formed out of the prepreg and a sheet of metal foil.

The respective components of the composition (X) will be described in detail.

The compound (A) will be described. The compound (A) facilitates lowering the dielectric constant and dielectric loss tangent of the cured product of the composition (X). The compound (A) is a polyphenylene ether, of which one terminal is modified with a group having an unsaturated double bond (unsaturated carbon-carbon double bond). That is to say, the compound (A) has, for example, a polyphenylene ether chain and a group having an unsaturated double bond which is bonded to one terminal of the polyphenylene ether chain.

Examples of such a group having an unsaturated double bond include a substituent expressed by the following Formula (1):

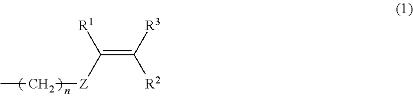

where n is a number falling within the range from 0 to 10, Z is an arylene group, R¹ to R³ are each independently a hydrogen atom or an alkyl group. If n is 0 in Formula (1), Z is directly bonded to the terminal of the polyphenylene ether chain.

The arylene group may be, for example, a monocyclic aromatic group such as a phenylene group, or a polycyclic aromatic group such as a naphthylene group. At least one hydrogen atom bonded to the aromatic ring in the arylene group may be replaced with a functional group such as an alkenyl group, an alkynyl group, a formyl group, an alkylcarbonyl group, an alkenylcarbonyl group, or an alkynylcarbonyl group. Note that these are only examples of the arylene group and should not be construed as limiting.

The alkyl group is preferably an alkyl group having 1 to 18 carbon atoms, and more preferably an alkyl group having 1 to 10 carbon atoms, for example. Specifically, the alkyl group may be, for example, a methyl group, an ethyl group, a propyl group, a hexyl group, or a decyl group. Note that these are only examples of the alkyl group and should not be construed as limiting.

The group having the unsaturated double bond may have, for example, a vinylbenzyl group (ethenylbenzyl group) such as a p-ethenylbenzyl group and an m-ethenylbenzyl group, a vinylphenyl group, an acrylate group, or a methacrylate group. The group having the unsaturated double bond preferably has a vinylbenzyl group, a vinylphenyl group, or a methacrylate group, among other things. If the group having the unsaturated double bond has an allyl group, the reactivity of the compound (A) tends to be low. Meanwhile, if the group having the unsaturated double bond has an acrylate group, the reactivity of the compound (A) tends to be too high.

A preferable specific example of the group having the unsaturated double bond may be a functional group including a vinylbenzyl group. Specifically, the group having the unsaturated double bond may be, for example, a substituent expressed by the following Formula (2):

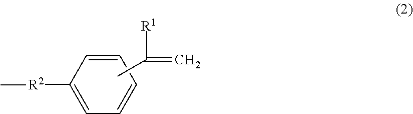

where R¹ is a hydrogen atom or an alkyl group having 1 to 10 carbon atoms, and R² is an alkylene group having either a single bond or 1 to 10 carbon atoms. R² is preferably an alkylene group having 1 to 10 carbon atoms.

The group having the unsaturated double bond may be a (meth)acrylate group. The (meth)acrylate group is expressed by, for example, the following Formula (3):

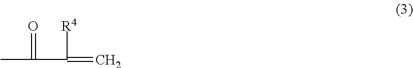

where R⁴ is a hydrogen atom or an alkyl group. The alkyl group is preferably an alkyl group having 1 to 18 carbon atoms, and more preferably an alkyl group having 1 to 10 carbon atoms. Specifically, the alkyl group may be, for example, a methyl group, an ethyl group, a propyl group, a hexyl group, or a decyl group. Note that these are only examples of the alkyl group and should not be construed as limiting.

As described above, compound (A) has a polyphenylene ether chain in its molecule. The polyphenylene ether chain has, for example, a repeating unit expressed by the following Formula (4):

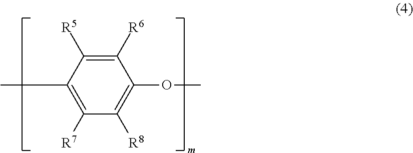

where m is a number falling within the range from 1 to 50 and R⁵ to R⁸ are each independently a hydrogen atom, an alkyl group, an alkenyl group, an alkynyl group, a formyl group, an alkylcarbonyl group, an alkenylcarbonyl group, or an alkynylcarbonyl group. Each of R⁵ to R⁸ is preferably a hydrogen atom or an alkyl group. The alkyl group is preferably an alkyl group having 1 to 18 carbon atoms, and more preferably an alkyl group having 1 to 10 carbon atoms, for example. Specifically, the alkyl group may be, for example, a methyl group, an ethyl group, a propyl group, a hexyl group, or a decyl group. The alkenyl group is preferably an alkenyl group having 2 to 18 carbon atoms, and more preferably an alkenyl group having 2 to 10 carbon atoms, for example. Specifically, the alkenyl group may be, for example, a vinyl group, an allyl group, or a 3-butenyl group. The alkynyl group is preferably an alkynyl group having 2 to 18 carbon atoms, and more preferably an alkynyl group having 2 to 10 carbon atoms, for example. Specifically, the alkynyl group may be, for example, an ethynyl group or a propa-2-in-1-yl group (propargyl group). The alkylcarbonyl group may be a carbonyl group replaced with an alkyl group and is preferably an alkylcarbonyl group having 2 to 18 carbon atoms, more preferably an alkylcarbonyl group having 2 to 10 carbon atoms. Specifically, the alkylcarbonyl group may be, for example, an acetyl group, a propionyl group, a butyryl group, an isobutyryl group, a pivaloyl group, a hexanoyl group, an octanoyl group, or a cyclohexylcarbonyl group. The alkenylcarbonyl group may be a carbonyl group replaced with an alkenyl group and is preferably an alkenylcarbonyl group having 3 to 18 carbon atoms, and more preferably an alkenylcarbonyl group having 3 to 10 carbon atoms, for example. Specifically, the alkenylcarbonyl group may be, for example, an acryloyl group, a methacryloyl group, or a crotonoyl group. The alkynylcarbonyl group may be a carbonyl group replaced with an alkynyl group and is preferably an alkynylcarbonyl group having 3 to 18 carbon atoms, and more preferably an alkynylcarbonyl group having 3 to 10 carbon atoms, for example. Specifically, the alkynylcarbonyl group may be, for example, a propioloyl group. Note that these are only examples of the alkyl group, alkenyl group, alkynyl group, formyl group, alkylcarbonyl group, alkenylcarbonyl group, and alkynylcarbonyl group and should not be construed as limiting.

The number average molecular weight of the compound (A) preferably falls within the range from 1000 to 5000, more preferably falls within the range from 1000 to 4000, and even more preferably falls within the range from 1000 to 3000. The number average molecular weight is obtained by converting the results of measurement by gel permeation chromatography (GPC) into a polystyrene equivalent value. If the compound (A) has the repeating unit expressed by the Formula (4) in the molecule, m in the Formula (4) is preferably such a numerical value that allows the number average molecular weight of the compound (A) to fall within the above preferred range. Specifically, it is preferable that m fall within the range from 1 to 50. If the number average molecular weight of the compound (A) falls within such a range, the compound (A) imparts excellent dielectric properties to the cured product of the composition (X) by the polyphenylene ether chain, and further improves the heat resistance and moldability of the cured product. The reason is probably as follows. If the number average molecular weight of the unmodified polyphenylene ether falls within the range from about 1000 to about 5000, the polyphenylene ether has a relatively low molecular weight and tends to decrease the heat resistance of the cured product. On the other hand, the compound (A) has an unsaturated double bond at one terminal, which would improve the heat resistance of the cured product. Furthermore, if the number average molecular weight of the compound (A) is 5000 or less, the moldability of the composition (X) would not be easily impaired. Therefore, the compound (A) would be able to improve not only the heat resistance of the cured product but also the moldability of the composition (X) as well. If the number average molecular weight of the compound (A) is 1000 or less, the glass transition temperature of the cured product is unlikely to decrease, and therefore, the cured product tends to have good heat resistance. In addition, since the polyphenylene ether chain in the compound (A) is unlikely to shorten, the cured product may easily maintain excellent dielectric properties due to the presence of the polyphenylene ether chain. Furthermore, if the number average molecular weight is 5000 or less, the compound (A) is easily dissolved in a solvent, and the storage stability of the composition (X) is unlikely to decrease. Besides, the compound (A) does not easily increase the viscosity of the composition (X), thus facilitating imparting good moldability to the composition (X).

It is preferable that the compound (A) contain no high molecular weight component having a molecular weight of 13000 or more or that the content of the high molecular weight component having a molecular weight of 13000 or more in the compound (A) be 5% by mass or less. That is to say, the content of the high molecular weight component having a molecular weight of 13000 or more in the compound (A) preferably falls within the range from 0% by mass to 5% by mass. In that case, the cured product may have particularly excellent dielectric properties, and the composition (X) may have particularly excellent reactivity and storage stability and may further have particularly excellent flowability. More preferably, the content of the high molecular weight component is 3% by mass or less. The content of the high molecular weight component may be calculated based on the molecular weight distribution measured by, for example, gel permeation chromatography (GPC).

The average number of groups having an unsaturated double bond (number of terminal functional groups) per molecule of the compound (A) is preferably 1 or more, more preferably 1.5 or more, even more preferably 1.7 or more, and particularly preferably 1.8 or more. In these cases, it is easy to ensure sufficient heat resistance for the cured product of the composition (X). The average number of groups having an unsaturated double bond is preferably 5 or less, more preferably 3 or less, even more preferably 2.7 or less, and particularly preferably 2.5 or less. In these cases, it is possible to prevent the reactivity and viscosity of the compound (A) from becoming excessively high, thus reducing the chances of causing inconveniences such as a decline in the storage stability of the composition (X) and/or the flowability of the composition (X). In addition, this also reduces the chances of leaving unreacted unsaturated double bonds after the composition (X) has been cured. The number of terminal functional groups of the compound (A) is the average value of substituents per molecule in 1 mol of the compound (A). This number of terminal functional groups may be obtained by, for example, if the compound (A) is synthesized by modifying the polyphenylene ether, measuring the number of hydroxyl groups in the compound (A), and by calculating the decrease in the number of hydroxyl groups in the compound (A) from the number of hydroxyl groups in the polyphenylene ether before modification. The decrease from the number of hydroxyl groups in the polyphenylene ether before the modification is the number of terminal functional groups. The number of hydroxyl groups remaining in the compound (A) may be determined by measuring the UV absorbance of a mixed solution obtained by adding a quaternary ammonium salt (tetraethylammonium hydroxide) that associates with hydroxyl groups to the solution of the compound (A).

The intrinsic viscosity of compound (A) preferably falls within the range from 0.03 dl/g to 0.12 dl/g, more preferably falls within the range from 0.04 dl/g to 0.11 dl/g, and even more preferably falls within the range from 0.06 dl/g to 0.095 dl/g. This facilitates lowering the dielectric constant and dielectric loss tangent of the cured product of the composition (X). In addition, the moldability of the composition (X) may be improved by imparting sufficient flowability to the composition (X).

Note that the intrinsic viscosity is measured in methylene chloride at 25° C., and more specifically, is the viscosity at 25° C. of a solution prepared by, for example, dissolving the compound (A) in methylene chloride at a concentration of 0.18 g/45 ml. This viscosity may be measured, for example, with a viscometer such as AVS500 Visco System manufactured by Schott Instruments GmbH.

Any method may be used without limitation to synthesize the compound (A). For example, the compound (A) may be synthesized by reacting polyphenylene ether with a compound in which a group having an unsaturated double bond and a halogen atom are bonded. More specifically, the polyphenylene ether and the compound in which the group having the unsaturated double bond and the halogen atom are bonded are dissolved in a solvent and stirred up. As a result, the polyphenylene ether reacts with the compound in which the group having the unsaturated double bond and the halogen atom are bonded, thus obtaining the compound (A).

The cross-linking agent (B) having a carbon-carbon double bond forms a cross-linked structure by reacting with the compound (A).

The cross-linking agent (B) contains at least one component selected from the group consisting of, for example, divinylbenzene, polybutadiene, alkyl (meth)acrylate, tricyclodecanol (meth)acrylate, fluorene (meth)acrylate, isocyanurate (meth)acrylate, and trimethylolpropane (meth)acrylate.

Among these components, the cross-linking agent (B) preferably contains polybutadiene in order to lower the dielectric constant. The percentage of the cross-linking agent (B) preferably falls within the range from 5% by mass to 70% by mass, more preferably falls within the range from 10% by mass to 60% by mass, and even more preferably falls within the range from 10% by mass to 50% by mass, with respect to the total content of the compound (A) and the cross-linking agent (B). In these cases, not only the moldability of the composition (X) but also the heat resistance of the cured product may be significantly improved, with the cured product allowed to maintain excellent dielectric properties due to the presence of the compound (A).

The composition (X) contains a hindered amine-based polymerization inhibitor (C). The hindered amine-based polymerization inhibitor (C) may contain a compound called a “hindered amine-based antioxidant” or a “hindered amine-based stabilizer.” Since the hindered amine-based polymerization inhibitor (C) has a radical scavenging action, the curing reaction may be retarded by inactivating radical active species in the composition (X) or a dried or semi-cured product thereof.

The hindered amine-based polymerization inhibitor (C) contains at least one component selected from the group consisting of, for example, 2,2,6,6-tetramethylpiperidine-1-oxyl and 4-hydroxy-2,2,6,6-tetramethylpiperidine-1-oxyl. Note that these are only examples of the components to be contained in the hindered amine-based polymerization inhibitor (C) and should not be construed as limiting.

The percentage of the hindered amine-based polymerization inhibitor (C) preferably falls within the range from 0.001% by mass to 0.048% by mass with respect to the total content of the compound (A) and the cross-linking agent (B). Setting this percentage at 0.001% by mass or more makes it easier for the hindered amine-based polymerization inhibitor (C) to sufficiently retard the curing reaction. Also, setting the percentage at 0.048% by mass or less reduces the chances of lowering the glass transition temperature of the cured product, and may also allow the glass transition temperature of the cured product to be 180° C. or higher. This makes the cured product easily applicable to the insulating layer of a printed wiring board, particularly a package substrate, as will be described later. The percentage of the hindered amine-based polymerization inhibitor (C) preferably falls within the range from 0.001% by mass to 0.036% by mass, more preferably falls within the range from 0.002% by mass to 0.025% by mass, and even more preferably falls within the range from 0.004% by mass to 0.015% by mass.

The composition (X) contains a solvent (D). The solvent (D) is preferably able to dissolve or disperse the compound (A) and the cross-linking agent (B) sufficiently, and preferably does not inhibit the reaction between the compound (A) and the cross-linking agent (B). For example, the solvent (D) preferably contains at least one component selected from the group consisting of an aliphatic hydrocarbon solvent, an aromatic hydrocarbon solvent, and a ketone solvent, and particularly preferably contains toluene. The components to be contained in the solvent (D) are not limited to these. The composition (X) containing a solvent facilitates impregnating the base material with the composition (X) when a prepreg is formed out of the composition (X). The content of the solvent in the composition (X) preferably falls within the range from 100% by mass to 500% by mass with respect to the total solid content. This makes the composition (X) homogenized enough to be easily impregnated into a fibrous base material.

The composition (X) may contain a flame retardant (E). This may further enhance the flame retardancy of the cured product of the composition (X). The flame retardant (E) contains at least one component selected from the group consisting of, for example, halogen-based flame retardants such as brominated flame retardants and phosphorus-based flame retardants. The halogen-based flame retardant contains at least one component selected from the group consisting of, for example, brominated flame retardants such as pentabromodiphenyl ether, octabromodiphenyl ether, decabromodiphenyl ether, tetrabromobisphenol A, and hexabromocyclododecane, and a chlorine-based flame retardant such as chlorinated paraffin. The phosphorus-based flame retardant contains at least one component selected from the group consisting of, for example, a phosphoric acid ester such as a condensed phosphoric acid ester and a cyclic phosphoric acid ester, a phosphazene compound such as a cyclic phosphazene compound, and a phosphinate flame retardant such as a phosphinic acid metal salt such as a dialkylphosphinic acid aluminum salt, and melamine-based flame retardants such as melamine phosphate and melamine polyphosphate. Note that these are only examples of the components to be contained in the flame retardant (E) and should not be construed as limiting.

The content of the flame retardant (E) preferably falls within the range from 5% by mass to 30% by mass with respect to the total content of the compound (A) and the cross-linking agent (B). The composition (X) containing such a flame retardant contributes to enhancing the flame resistance of the laminate.

The composition (X) may contain an inorganic filler (F). The inorganic filler (F) may enhance the heat resistance and flame retardancy of the cured product. If the composition (X) contains the compound (A), the cured product of the composition (X) tends to have a lower crosslink density and a higher coefficient of linear expansion (among other things, a coefficient of linear expansion al at a temperature lower than the glass transition temperature) than the cured product such as an epoxy resin composition for a general insulating base material. However, the composition (X) containing the inorganic filler (F) enables reducing the coefficient of linear expansion (particularly, the coefficient of linear expansion al) of the cured product and increasing the tenacity of the cured product while lowering the dielectric constant of the cured product, increasing the heat resistance and flame retardance of the cured product, and reducing an increase in the viscosity of the composition (X).

The inorganic filler (F) may contain at least one component selected from the group consisting of, for example, silica, alumina, talc, aluminum hydroxide, magnesium hydroxide, titanium oxide, mica, aluminum borate, barium sulfate, and calcium carbonate. The inorganic filler (F) may be surface-treated with a silane coupling agent. The silane coupling agent may increase the heat resistance of the insulating layer at the time of moisture absorption when the insulating layer of the laminate is formed out of the composition (X) and may also increase the peel strength between the insulating layer and a sheet of metal foil stacked on the insulating layer. The silane coupling agent contains at least one component selected from the group consisting of, for example, vinylsilane, styrylsilane, methacrylic silane, and acrylic silane.

If the composition (X) contains the inorganic filler (F), the percentage of the inorganic filler (F) with respect to the total solid content of the composition (X) preferably falls within the range from 5% by mass to 60% by mass, more preferably falls within the range from 10% by mass to 60% by mass, and even more preferably falls within the range from 15% by mass to 50% by mass.

As described above, the composition (X) may contain the composite particles (I).

As described above, the composite particles (I) each have a core containing a fluororesin and a shell containing a silicon oxide. The core preferably consists essentially of the fluororesin but may further contain components other than the fluororesin as long as the advantages of the present embodiment are not impaired. The shell preferably consists essentially of the silicon oxide but may further contain components other than the silicon oxide as long as the advantages of the present embodiment are not impaired. The mean particle size of the core in the composite particles (I) preferably falls within the range from 0.1 μm to 20 μm. Setting the mean particle size at 0.1 μm or more reduces the chances of making the resin flowability too low. Setting the mean particle size at 20 μm or less reduces the chances of causing a decrease in the peel strength between the insulating layer and the sheet of metal foil stacked on the insulating layer. The mean particle size more preferably falls within the range from 0.5 μm to 5 μm. The mean particle size of the core is an arithmetic mean particle size obtained based on the result of measuring the particle size distribution of only the core not covered with the shell by laser diffraction method. A core that is not covered with a shell may be obtained by, for example, treating the composite particles with a desmear treatment solution. Further, the composite particles are shot with a transmission electron microscope (TEM) or a scanning transmission electron microscope (STEM), and the longest size of the core portion of the composite particles is measured based on the image thus captured. The arithmetic mean of these results of measurement may be regarded as the mean particle size of the core. The mean particle size may be determined based on the measurement results obtained from at least 30 cores.

In particular, it is preferable that the silicon oxide in the composite particles (I) be treated with phenylamino. That is to say, the shell of the composite particles (I) preferably includes a silicon oxide treated with a compound having a phenylamino group (C₆H₅—NH—). This significantly reduces the chances of causing a decrease in the peel strength between the insulating layer and the sheet of metal foil stacked on the insulating layer. In addition, this increases the degree of adhesion between the resin and the composite particles (I) in the cured product, thus facilitating improving the insulation reliability of the insulating layer.

The shell is formed out of, for example, silicon oxide particles having a smaller particle size than the core. In this case, for example, irradiating, with an electron beam, the silicon oxide particles arranged on the surface of the particles (fluororesin particles) consisting of only the core causes the silicon oxide particles (I) to adhere to the fluororesin particles, thus forming a shell. As a result, composite particles each having a core and a shell are obtained. Note that this an exemplary method of forming the shell and should not be construed as limiting. The composite particles (I) may be obtained by adhering the silicon oxide particles onto the fluororesin particles or precipitating the silicon oxide particles on the fluororesin particles. For this purpose, for example, a method of obtaining composite particles (I) by spraying silicon oxide particles onto molten fluororesin particles and combining the silicon oxide particles with the fluororesin particles may be used. Alternatively, a method of obtaining composite particles (I) by precipitating a silicon oxide on the surface of fluororesin particles when the fluororesin particles are dispersed and precipitated in a liquid may also be used. Still alternatively, the shell may be in a state in which silicon oxide particles are densely adhered and supported around the core. Yet alternatively, the shell may also form a layer in which the silicon oxide particles are continuously connected together to surround the core.

If the silicon oxide in the composite particles (I) is treated with phenylamino, the silicon oxide particles are treated with phenylamino before the composite particles (I) are formed. In that case, as the compound having a phenylamino group (C₆H₅—NH—), a silane compound having a phenylamino group such as N-phenyl-3-aminopropyltrimethoxysilane may be used, for example. When the phenylamino treatment is carried out, silicon oxide particles are treated with a compound having a phenylamino group by a vapor phase method or a liquid phase method, for example.

The content of the composite particles (I) preferably falls within the range from 10 parts by mass to 200 parts by mass with respect to 100 parts by mass in total of the compound (A) and the cross-linking agent (B). Setting the content of the composite particles (I) at 10 parts by mass or more makes it easier for the composite particles (I) to particularly significantly increase the heat resistance and flame retardancy of the cured product, and particularly significantly lower the coefficient of linear expansion and dielectric constant of the insulating layer. In addition, setting the content of the composite particles (I) at 200 parts by mass or less reduces the chances of not only causing a decrease in the degree of adhesion between the cured product and a metal such as copper but also causing an excessive increase in the resin flowability of the prepreg.

The composition (X) may contain a silane coupling agent (G). In that case, the silane coupling agent (G) is a component that is not used for the surface treatment of the inorganic filler. In that case, the silane coupling agent (G) may increase not only the heat resistance of the insulating layer at the time of moisture absorption in a situation where the insulating layer of the laminate is formed out of the composition (X) but also the peel strength between the insulating layer and the sheet of metal foil stacked on the insulating layer. The silane coupling agent (G) contains at least one component selected from the group consisting of, for example, vinylsilane, styrylsilane, methacrylic silane, and acrylic silane.

The percentage of the silane coupling agent (G) to the total content of the compound (A) and the cross-linking agent (B) preferably falls within the range from 0.3% by mass to 5% by mass. Using such a silane coupling agent (G) would increase the delamination strength.

The composition (X) may contain a reaction initiator (H). The reaction initiator (H) may contain an appropriate compound capable of accelerating the curing reaction between the compound (A) and the cross-linking agent (B). Specifically, the reaction initiator (H) may contain at least one compound selected from the group consisting of, for example, oxidants such as a, a′-bis (t-butylperoxy-m-isopropyl) benzene, 2,5-dimethyl-2,5-di(t-butylperoxy)-3-hexin, benzoyl peroxide, 3,3′,5,5′-tetramethyl-1,4-diphenoquinone, Chloranil, 2,4,6-tri-t-butylphenoxyl, t-butylperoxyisopropyl monocarbonate, and azobisisobutyronitrile. If necessary, the reaction initiator (H) may contain, for example, a carboxylic acid metal salt in addition to the oxidant. This may further accelerate the curing reaction. Note that these are only exemplary components to be contained in the reaction initiator (H) and should not be construed as limiting.

The reaction initiator (H) preferably contains a, a′-bis (t-butylperoxy-m-isopropyl) benzene, among other things. In that case, a, a′-bis (t-butylperoxy-m-isopropyl) benzene, having a relatively high reaction start temperature, reduces the chances of the curing reaction proceeding excessively when the composition (X) is heated to be dried or semi-cured. Furthermore, a, a′-bis (t-butylperoxy-m-isopropyl) benzene has low volatility, and therefore, hardly vaporizes during storage and heating of the composition (X) and rarely impairs the stability of the composition (X).

The composition (X) may contain additive(s) other than these components. The additive(s) contain at least one component selected from the group consisting of, for example, defoamers such as silicone-based defoamers and acrylic acid ester-based defoamers, heat stabilizers, antistatic agents, ultraviolet absorbers, dyes and pigments, lubricants, and dispersants such as wet dispersants. Note that these are only exemplary components to be contained in the additive(s) and should not be construed as limiting.

The gel time of the dried or semi-cured product of the composition (X) recovered from the prepreg is preferably measured, in accordance with the JIS C6521 standard, 200 seconds to 600 seconds at 170° C.

If the solid content ratio of the composition (X) is adjusted to 68% by mass, the viscosity of the composition (X) at 25° C. preferably falls within the range from 200 mPa·s to 2000 mPa·s. This makes the composition (X) easily impregnated into the fibrous base material. This viscosity is measured with a type B viscometer.

These advantageous properties of the composition (X) may be realized within the above-described range of the chemical makeup of the composition (X).

The composition (X) may be prepared, for example, as follows. First, components that may be dissolved in an organic solvent, such as the compound (A) and the cross-linking agent (B), are mixed with the organic solvent to prepare a mixture. At this time, the mixture may be heated as appropriate. Thereafter, an optional component not dissolved in the organic solvent, such as an inorganic filler, is added to the mixture and then dispersed using a ball mill, a bead mill, a planetary mixer, or a roll mill, for example, to prepare composition (X) in a varnish state.

A prepreg may be formed out of the composition (X). The prepreg includes a base material, and a dried or semi-cured product of the composition (X) impregnated into the base material. The prepreg may be formed by, for example, a method including the steps of impregnating the base material with the composition (X); and heating the composition (X) after the step of impregnating.

The base material may be, for example, a fibrous base material. The fibrous base material is selected from the group consisting of, for example, glass cloth, aramid cloth, polyester cloth, glass non-woven fabric, aramid non-woven fabric, polyester non-woven fabric, pulp paper, and linter paper. Making the fibrous base material of glass cloth facilitates increasing the mechanical strength of a laminate formed out of the prepreg. The glass cloth is preferably flattened. The thickness of the fibrous base material may fall within the range from, for example, 0.04 mm to 0.3 mm.

The step of impregnating allows the base material to be impregnated with the composition (X) by, for example, immersing the base material in the composition (X) or applying the composition (X) onto the base material. If necessary, the base material may be immersed in the composition (X) multiple times or the composition (X) may be applied onto the base material multiple times.

Subsequently, the step of heating includes heating the composition (X) impregnated into the base material to cause the composition (X) to be dried or semi-cured. In this manner, a prepreg including the base material and a dried or semi-cured product of the composition (X) impregnated into the base material is obtained.

According to this embodiment, even if the composition (X) is heated to be dried or semi-cured, the curing reaction of the composition (X) does not proceed smoothly as described above. This makes it easier to control the resin flowability of the prepreg while sufficiently vaporizing the solvent and reducing the volume of the residual solvent.

Since the resin flowability of the prepreg is controlled by adjusting the heating condition in the step of heating, the evaluated value of resin flowability of the prepreg preferably falls within the range from 4% to 25%. Note that the method for evaluating the resin flowability will be described later with respect to specific examples. Controlling the evaluated value of resin flowability at 4% or more facilitates, when a laminate is manufactured from a prepreg by the batch press method (particularly when the prepreg is stacked on the conductor wiring), sufficiently filling the gaps between respective portions of the conductor wiring with an insulating layer formed out of the prepreg. In addition, controlling the evaluated value of resin flowability at 25% or less reduces, when a laminate is manufactured from a prepreg by the continuous press method, the chances of causing a dispersion in the thickness of an insulating layer formed out of the prepreg. The evaluated value of resin flowability more preferably falls within the range from 2% to 15%, and even more preferably falls within the range from 3% to 13%.

In addition, since the volume of the residual solvent in the prepreg is controlled by adjusting the heating condition, the prepreg preferably has a volatile content less than 1.5% by volatile evaluation. This reduces the chances of causing outgassing even if a prepreg is heated to form a laminate out of the prepreg. Note that the volatile evaluation method will be described later with respect to specific examples. The volatile content is particularly preferably equal to 0%.

The condition for heating the composition (X) in the step of heating (i.e., the condition for heating the composition (X) to form a dried or semi-cured product of the prepreg) is set appropriately such that the evaluated resin flowability and the volatile evaluation fall within the above-described ranges. Alternatively, the step of heating may also be a multi-stage step including multiple steps with respectively different heating temperatures.

In particular, the step of heating preferably satisfies the heating condition expressed by the following mathematical formula (I). Note that the step of heating herein refers to the step of increasing the temperature of the composition (X) using a device such as a heater. In the mathematical formula (I), i indicates the number of process steps having respectively different heating temperatures and included in the step of heating, Tpₙ indicates a heating temperature (° C.) in an n^{th} process step out of the i process steps, and Tmₙ indicates a heating time (sec) in the n^{th} process step out of the i process steps. The condition that satisfies this mathematical formula (I) facilitates controlling the resin flowability of the prepreg to easily fill the gaps between respective portions of the conductor wiring with the insulating layer according to the batch press method and to reduce the chances of causing a dispersion in the thickness of the insulating layer according to the continuous press method. In addition, this also facilitates decreasing the volume of the residual solvent in the prepreg. In this step of heating, the heating temperature preferably falls within the range from 100° C. to 150° C.

$$4500 ≦ {\sum }_{n = 1}^{i} ( {Tp}_{n} + {Tm}_{n} ) ≦ 10000 \qquad ( 1 )$$

The processes of manufacturing a laminate and a printed wiring board using the prepreg will be described. According to this embodiment, when a laminate and a printed wiring board are manufactured using the prepreg, the prepreg is easily applicable to both the roll press method and the batch press method as described above.

If a laminate is manufactured by the roll press method, a long prepreg and a long sheet of metal foil are stacked one on top of the other while being transported continuously and then hot pressed using a continuous press machine such as a roll press machine or a double belt press machine. The hot press condition may be set appropriately. For example, the heating temperature preferably falls within the range from 250° C. to 300° C., the applied pressure preferably falls within the range from 1 MPa to 5 MPa, and the heating time preferably falls within the range from 4 minutes to 10 minutes. In this manner, a laminate including an insulating layer formed out of the prepreg and a sheet of metal foil stacked on the insulating layer is manufactured.

Alternatively, a long prepreg may be manufactured by either applying the composition (X) onto a long base material or immersing the base material in the composition (X) while transporting the base material and by further heating the composition (X) while continuously transporting this base material. Optionally, a laminate may also be manufactured in the same way as described above while further transporting the prepreg continuously.

As can be seen, forming a laminate out of the composition (X) by the roll press method reduces the chances of not only causing a dispersion in the thickness of the insulating layer but also causing outgassing during the manufacturing process of the laminate as described above.

If a laminate is manufactured by the batch press method, the prepreg is stacked, for example, over a core member including an insulating layer and conductor wiring to cover the conductor wiring and then a sheet of metal foil is further stacked over the prepreg, thereby forming a laminate. Optionally, the laminate may further include another prepreg, sheet of metal foil, or core member, for example. This laminate is arranged between a pair of heating platens and thereby hot pressed. The hot press condition may be set appropriately. For example, the heating temperature preferably falls within the range from 170° C. to 220° C., the applied pressure preferably falls within the range from 1.5 MPa to 5 MPa, and the heating time preferably falls within the range from 60 minutes to 150 minutes. In this manner, a laminate including an insulating layer formed out of the prepreg and a sheet of metal foil stacked on the insulating layer is manufactured. Optionally, the laminate may further include an insulating layer and conductor wiring derived from the core member.

As can be seen, forming a laminate out of the composition (X) by the batch press method facilitates filling the gaps between respective portions of the conductor wiring with the insulating layer and reduces the chances of causing outgassing during the manufacturing process of the laminate, as described above.

Note that when a laminate is manufactured by the batch press method, the laminate may include no core member. For example, the laminate may include a prepreg and a sheet of metal foil stacked on one surface of the prepreg. Alternatively, the laminate may include a prepreg and two sheets of metal foil respectively stacked on both surfaces of the prepreg.

When a printed wiring board is manufactured, conductor wiring is formed by subjecting a sheet of metal foil stacked on the insulating layer of the laminate to an etching process. In this manner, a printed wiring board including the insulating layer formed out of the prepreg and the conductor wiring may be manufactured.

The printed wiring board according to this embodiment is preferably a package board, for example. That is to say, a semiconductor package is preferably fabricated by using the printed wiring board according to this embodiment as a package board and mounting chip components such as semiconductor chips on the package board. This enables providing a semiconductor package suitably used in radio frequency applications, even though its thickness is thinner than known ones. Note that the package board is only an exemplary one of various applications of the printed wiring board according to this embodiment.

### EXAMPLES

Next, more specific examples of the exemplary embodiment will be described. Note that the examples to be described below are only examples of the present disclosure and should not be construed as limiting.

1. Preparation of Composition

A composition was obtained by mixing the components shown in Tables 1 and 2. The details of the components shown in Tables 1 and 2 are as follows.

The modified polyphenylene ether compound used had been synthesized in the following procedure.

Polyphenylene ether was reacted with chloromethylstyrene to obtain a modified polyphenylene ether.

Specifically, first, 200 g of polyphenylene ether (a polyphenylene ether having the structure expressed by the following Formula (5); SA90 manufactured by SABIC Innovative Plastics; having an intrinsic viscosity (IV) of 0.083 dl/g, a number of terminal hydroxyl groups per molecule of 1.9, and a weight average molecular weight Mw of 2000), 30 g of a mixture having a mass ratio of 50:50 of p-chloromethylstyrene and m-chloromethylstyrene (chloromethylstyrene: CMS manufactured by Tokyo Chemical Industry Co., Ltd.), and 1.227 g of tetra-n-butylammonium bromide and 400 g of toluene as phase transfer catalysts were put into a three-necked flask having a capacity of 1 liter equipped with a temperature controller, a stirrer, a cooling facility, and a dropping funnel. In this manner, a reaction solution was obtained.

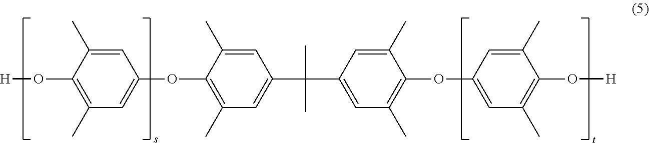

The reaction solution was stirred up until polyphenylene ether, chloromethylstyrene, and tetra-n-butylammonium bromide were dissolved in toluene. At that time, the reaction solution was gradually heated until the solution temperature finally reached 75° C. Then, an aqueous sodium hydroxide (containing 20 g of sodium hydroxide and 20 g of water) was added dropwise as an alkali metal hydroxide to the reaction solution for 20 minutes. Then, the reaction solution was further stirred up at 75° C. for 4 hours. Next, after the reaction solution was neutralized with an aqueous hydrochloric acid having a concentration of 10% by mass, a lot of methanol was added thereto. In this manner, a precipitate was formed in the reaction solution. That is to say, the product contained in the reaction solution was reprecipitated. Then, the precipitate was taken out from the reaction solution by filtration, washed three times with a mixed solution containing methanol and water at a mass ratio of 80 to 20, and then dried at 80° C. for 3 hours under a reduced pressure.

The solid thus obtained was analyzed with 1H-NMR (400 MHz, CDCl₃, TMS). As a result, a peak derived from ethenylbenzyl was recognized at 5 to 7 ppm. Thus, it was confirmed that the solid thus obtained was a modified polyphenylene ether having the group expressed by the Formula (1) at a terminal of its molecule. Specifically, it was confirmed that the modified polyphenylene ether was a polyphenylene ether that had been turned into ethenylbenzyl.

In addition, the number of terminal functional groups of the modified polyphenylene ether was measured as follows.

First, the modified polyphenylene ether was accurately weighed. The weight of the modified polyphenylene ether at that time was supposed to be X (mg). Then, the modified polyphenylene ether thus weighed was dissolved in 25 mL of methylene chloride, and 100 μL of an ethanol solution of 10% by mass of tetraethylammonium hydroxide (TEAH) (where TEAH: ethanol (volume ratio)=15:85) was added to the solution thus obtained, and then the absorbance (Abs) of the solution at 318 nm was measured with a UV spectrophotometer (UV-1600 manufactured by Shimadzu Corporation). Then, based on the measurement results, the volume of terminal hydroxyl group per weight of the modified polyphenylene ether was calculated by the following formula.

Volume of terminal hydroxyl group (μmol/g)=[(25×Abs)/(ε×OPL×X)]×10⁶ where ε indicates an absorption coefficient, which was 4700 L/mol·cm in this test, and OPL is the cell optical path length, which was 1 cm in this test.

Since the volume of terminal hydroxyl groups was calculated to be approximately zero, almost all the hydroxyl groups of the polyphenylene ether before modification turned out to have been modified. Thus, it was discovered that the number of terminal hydroxyl groups of the polyphenylene ether yet to be modified was equal to the number of terminal functional groups of the modified polyphenylene ether. That is to say, the number of terminal functional groups per molecule of the modified polyphenylene ether was 1.9.

In addition, the intrinsic viscosity (IV) at 25° C. of a methylene chloride solution of the modified polyphenylene ether was measured. Specifically, a methylene chloride solution (with a liquid temperature of 25° C.) with a concentration of 0.18 g/45 ml of the modified polyphenylene ether had its intrinsic viscosity measured with a viscometer (AVS500 Visco System manufactured by Schott Instruments GmbH). As a result, the intrinsic viscosity (IV) was 0.086 dl/g.

In addition, the molecular weight distribution of the modified polyphenylene ether was measured by GPC (gel permeation chromatography). Based on the molecular weight distribution thus obtained, a weight average molecular weight (Mw) and the content of high molecular weight components having a molecular weight of 13000 or more were calculated. Furthermore, the content of the high molecular weight components was specifically calculated based on the ratio of a peak area represented by a curve showing the molecular weight distribution obtained by GPC. As a result, Mw was 2300. The content of the high molecular weight components was 0.1% by mass.
Polybutadiene oligomer: product number B-1000 manufactured by Nippon Soda Co., Ltd.;
Flame Retardant #1: phosphinate compound (aluminum trisdiethyl phosphinate), product name Exolit OP935 manufactured by Clariant Chemicals;
Flame retardant #2: phosphoric acid ester compound (aromatic condensed phosphoric acid ester compound), product number PX-200 manufactured by Daihachi Chemical Industry Co., Ltd.;
Inorganic filler: spherical silica, having a median size of 3 μm; product number SC2300-SVJ manufactured by Admatechs;
Silane coupling agent: 3-methacryloxypropyltrimethoxysilane, product number ICBM-503 manufactured by Shin-Etsu Chemical Co., Ltd.;
Hindered amine-based polymerization inhibitor: 4-hydroxy-2,2,6,6-tetramethylpiperidine-1-oxyl, product name ADK STAB LA-7RD manufactured by ADEKA CORPORATION;
Composite particles #1: composite particles having a core (with a mean particle size of 3 μm) made of polytetrafluoroethylene and a shell made of non-surface-treated silica particles (with a mean particle size 0.01 μm);
Composite particles #2: composite particles having a core (with a mean particle size of 3 μm) made of polytetrafluoroethylene and a shell made of silica particles (with a mean particle size 0.01 μm) surface-treated with N-phenyl-3-aminopropyltrimethoxysilane;
Composite particles #3: composite particles having a core (with a mean particle size of 1 μm) made of polytetrafluoroethylene and a shell made of silica particles (with a mean particle size of 0.01 μm) surface-treated with N-phenyl-3-aminopropyltrimethoxysilane;
Composite particles #4: composite particles having a core (with a mean particle size of 0.1 μm) made of polytetrafluoroethylene and a shell made of silica particles (with a mean particle size of 0.01 μm) surface-treated with N-phenyl-3-aminopropyltrimethoxysilane; and
Composite particles #5: composite particles having a core (with a mean particle size of 15 μm) made of polytetrafluoroethylene and a shell made of silica particles (with a mean particle size of 0.01 μm) surface-treated with N-phenyl-3-aminopropyltrimethoxysilane.

2. Forming Prepreg

A prepreg having a resin content of 74% by mass was formed by impregnating glass cloth (product number NE1017 manufactured by Nitto Boseki Co., Ltd., and having a thickness of 14 μm) with the composition and then heating the glass cloth impregnated with the composition under the conditions shown in Tables 1 and 2.

3. Evaluation Tests

(1) Volatile Evaluation

Volatile evaluation was carried out as follows in accordance with Section 5.6 of JIS C6521 (1990). The prepreg was cut off to obtain three test pieces, each having dimensions of 100±1 mm×100±1 mm. The test piece was weighed with an electronic scale. The value up to the order of 0.0001 g obtained by this weighing was represented by Wa (g). The test piece was loaded into a circulating hot air dryer controlled at 163±2° C., unloaded from the circulating hot air dryer in 15 minutes after the test piece had been loaded thereto, and loaded into a desiccator promptly. The test piece was unloaded from the desiccator and weighed with an electronic scale. The value up to the order of 0.0001 g obtained by this weighing was represented by Wb (g). The volatile content was calculated by the following formula:

Volatile content (%)={(Wa−Wb)/Wa}×100

The value calculated by this formula had its third decimal place rounded off to the second decimal place. The value thus obtained was regarded as an evaluated value.

(2) Evaluation of Resin Flowability

The prepreg was cut off to obtain a plurality of test pieces, each having dimensions of 100±1 mm×100±1 mm. A laminate obtained by stacking a plurality of test pieces one on top of another was weighed with an electronic scale, and the number of the test pieces was adjusted so that the weight of the laminate was about 20 g. The value to the order of 0.01 g obtained by weighing the laminate was represented by A (g). The laminate was sandwiched between two halves of a folded sheet of release paper. The laminate sandwiched in the folded sheet of release paper was then sandwiched between a pair of release films, and then the assembly was sandwiched between a pair of iron plates. Then, the stack was hot pressed for 15 minutes with a press with an automatic temperature controller (flow tester) at a temperature of 170±2° C. under a pressure of 20±0.3 kg/cm². Subsequently, a disk having a diameter of 81.1±0.05 (mm) was punched from a central portion of the laminate and was weighed with an electronic scale. The value to the order of 0.01 g obtained by this weighing was represented by B (g). The resin flowability was calculated by the following formula:

Resin flowability=(A×1.03−2×B)/(A×1.03)×100(%)

The value calculated by this formula had its second decimal place rounded off to the first decimal place. The value thus obtained was regarded as an evaluated value.

(3) Evaluation of Batch Press Method

(3-1) Evaluation of Heat Resistance of Oven

A sheet of copper foil having a thickness of 3 μm was prepared as a sheet of metal foil. A laminate was obtained by sandwiching two prepregs between two sheets of metal foil. The laminate was hot pressed using a heating platen. The condition for this hot pressing included a temperature increase rate of 3° C./min, a highest heating temperature of 200° C., and a holding time of 90 minutes. As a result, a laminate including an insulating layer formed out of the prepreg was obtained.

The laminate was cut off to obtain five test pieces, each having dimensions of 50 mm×50 mm. The test pieces were heated in a convection oven at 160° C. for 1 hour, and then the appearance of the test pieces was inspected. If all five test pieces had no appearance abnormality as a result, the test pieces were graded A. If one to four test pieces had appearance abnormality, the test pieces were graded B. If all five test pieces had appearance abnormality, the test pieces were graded C.

(3-2) Fillability

A sheet of copper foil having a thickness of 3 μm was prepared as a sheet of metal foil. A printed wiring board including conductor wiring of copper as a core member and having a conductor wiring thickness of 18 μm and a residual copper ratio of 50% was prepared. A single prepreg was stacked on the core member so as to cover the conductor wiring with the prepreg, and then a sheet of metal foil was further stacked on the prepreg to obtain a laminate. The laminate was hot pressed using a heating platen. The conditions for this hot pressing included a temperature increase rate of 3° C./min, a highest heating temperature of 200° C., and a holding time of 90 minutes. In this manner, a laminate including an insulating layer formed out of the prepreg was obtained.

After the sheet of metal foil was entirely removed from this laminate by etching, the insulating layer was observed to see if the gaps between respective portions of the conductor wiring were filled with the insulating layer. If the gaps failed to be filled nowhere with the insulating layer, then the laminate was graded A. If the gaps failed to be filled here and there with the insulating layer, then the laminate was graded B. If the gaps failed to be filled everywhere with the insulating layer, then the laminate was graded C.

(3-3) Dielectric Constant (Dk)

A laminate was obtained by the same method as the one described for the “(3-1) Evaluation of heat resistance of oven” section. An unclad plate was formed by removing the sheet of metal foil from this laminate by etching process. The relative dielectric constant of this unclad plate at a test frequency of 1 GHz was measured in accordance with IPC TM-650 2.5.5.5. At the time of measurement, an RF impedance analyzer (model number HP4291B) manufactured by Agilent Technologies, Inc. was used as a measuring device.

(3-4) Copper Foil Peel Strength

A laminate was obtained by the same method as the one described for the “(3-1) Evaluation of heat resistance of oven” section. The peel strength at the time of peeling a metal layer (sheet of metal foil) from the insulating layer of this laminate was measured in accordance with the JIS C 6481 standard. At the time of measurement, the sheet of metal foil formed to have a width of 5 mm and a length of 100 mm was peeled off from the insulating layer at a rate of 50 mm/min by a tensile tester, and the peel strength at that time was measured.

(3-5) Coefficient of Linear Expansion (CTE)

A laminate was obtained by the same method as the one described for the “(3-1) Evaluation of heat resistance of oven” section. An unclad plate was formed by removing a sheet of metal foil from this laminate by etching process. The coefficient of linear expansion al of this unclad plate in a direction perpendicular to the thickness direction at a temperature lower than the glass transition temperature was measured by the TMA (thermo-mechanical analysis) method in accordance with the JIS C6481 standard. At the time of the measurement, a dynamic mechanical analyzer (viscoelasticity spectrometer; model number DMA7100 manufactured by Hitachi High-Tech Science Corporation) was used to make the measurement in a temperature range from 30° C. to 300° C., and a coefficient of linear expansion was obtained based on some of the results thus obtained corresponding to a range lower than the glass transition temperature.

(4) Evaluation by Continuous Press Method

(4-1) Evaluation of Glass Transition Temperature

A sheet of copper foil having a thickness of 18 μm was prepared as a sheet of metal foil. While two sheets of metal foil and the two prepregs were transported continuously, the two prepregs were sandwiched between the two sheets of metal foil and hot pressed by passing them between two heating rolls. The condition for this hot pressing included a heating temperature of 250° C., a press pressure of 4 mPa, and a heating and pressurizing time of 5 minutes. In this manner, a laminate including an insulating layer formed out of a prepreg was obtained.

The sheet of metal foil was entirely removed from the laminate by etching process. Subsequently, with a tensile module of a viscoelastic spectrometer (DMA7100) manufactured by Hitachi High-Tech Science Corporation, the viscoelasticity of the insulating layer was measured under the condition including a frequency of 10 Hz, a temperature increase rate of 5° C./min, and a temperature range from room temperature to 280° C. The temperature at which tan δ thus obtained reached a local maximum value was defined to be the glass transition temperature.

(4-2) Fillability

A sheet of copper foil having a thickness of 18 μm was prepared as a sheet of metal foil. A printed wiring board including conductor wiring of copper as a core member and having a conductor wiring thickness of 18 μm and a residual copper ratio of 50% was prepared. While the sheet of metal foil, the core member, and a single prepreg were transported continuously, the single prepreg was stacked on the core member so as to cover the conductor wiring with the prepreg, and then the sheet of metal foil was further stacked on the prepreg to obtain a laminate. The laminate was hot pressed by passing the laminate between two heating rolls. The conditions for this hot pressing included a heating temperature of 250° C., a press pressure of 4 mPa, and a heating and pressurizing time of 5 minutes. In this manner, a laminate including an insulating layer formed out of the prepreg was obtained.

After the sheet of metal foil was entirely removed from this laminate by etching process, the insulating layer was observed to see if the gaps between respective portions of the conductor wiring were filled with the insulating layer. If the gaps failed to be filled nowhere with the insulating layer, then the laminate was graded A. If the gaps failed to be filled here and there with the insulating layer, then the laminate was graded B. If the gaps failed to be filled everywhere with the insulating layer, then the laminate was graded C.

(4-3) Evaluation of Thickness Accuracy

A laminate was obtained by the same method as the one described for the “(4-1) Evaluation of glass transition temperature” section. The thickness of the insulating layer of this laminate was measured at 12 points at intervals of 3 cm in the TD (transverse direction) with a micrometer. If the maximum value of the measured values was Av×1.10 or less and the minimum value thereof was Av×0.9 or more with respect to the average value (Av) of the 12 measured values thus obtained, the laminate was graded A. Otherwise, the laminate was graded B.

(4-4) Dielectric Constant (Dk)

A laminate was obtained by the same method as the one described for the “(4-1) Evaluation of glass transition temperature” section. An unclad plate was formed by removing the sheet of metal foil from this laminate by etching process. The relative dielectric constant of this unclad plate at a test frequency of 1 GHz was measured in accordance with IPC TM-650 2.5.5.5. At the time of measurement, an RF impedance analyzer (model number HP4291B) manufactured by Agilent Technologies, Inc. was used as a measuring device.

(4-5) Copper Foil Peel Strength

A laminate was obtained by the same method as the one described for the “(4-1) Evaluation of glass transition temperature” section. The peel strength at the time of peeling a metal layer (sheet of metal foil) from the insulating layer of this laminate was measured in accordance with the JIS C 6481 standard. At the time of measurement, a sheet of metal foil formed to have a width of 5 mm and a length of 100 mm was peeled off from the insulating layer at a rate of 50 min/min by a tensile tester, and the peel strength at that time was measured.

(4-6) Coefficient of Linear Expansion (CTE)

A laminate was obtained by the same method as the one described for the “(4-1) Evaluation of glass transition temperature” section. An unclad plate was formed by removing a sheet of metal foil from this laminate by etching process. The coefficient of linear expansion of this unclad plate in a direction perpendicular to the thickness direction at a temperature lower than the glass transition temperature was measured by the TMA (thermo-mechanical analysis) method in accordance with the JIS C6481 standard. At the time of the measurement, a dynamic mechanical analyzer (viscoelasticity spectrometer with model number DMA7100 manufactured by Hitachi High-Tech Science Corporation) was used to make the measurement in a temperature range from 30° C. to 300° C., and a coefficient of linear expansion was obtained based on some of the results thus obtained corresponding to a range lower than the glass transition temperature.

TABLE 1

| | | | Examples | | | | | |
|---|---|---|---|---|---|---|---|---|
| | | | 1 | 2 | 3 | 4 | 5 | 6 |
| Chemical | Modified polyphenylene ether compound | | 85 | 85 | 85 | 85 | 85 | 85 |
| makeup | Polybutadiene | | 15 | 15 | 15 | 15 | 15 | 15 |
| (parts by | Flame retardant 1 | | 12 | 12 | 12 | 12 | 12 | 12 |
| mass) | Flame retardant 2 | | 6 | 6 | 6 | 6 | 6 | 6 |
| | Inorganic filler | | 90 | 90 | 90 | 90 | 90 | 90 |
| | Silane coupling agent | | 1 | 1 | 1 | 1 | 1 | 1 |
| | Hindered amine-based polymerization inhibitor | | 0.006 | 0.012 | 0.036 | 0.048 | 0.006 | 0.002 |
| | Composite particles 1 | | | | | | | |
| | Composite particles 2 | | | | | | | |
| | Composite particles 3 | | | | | | | |
| | Composite particles 4 | | | | | | | |
| | Composite particles 5 | | | | | | | |
| | Toluene | | 100 | 100 | 100 | 100 | 100 | 100 |
| Heating | Step 1 | Heating temperature (° C.) | 120 | 120 | 120 | 120 | 120 | 120 |
| step | | Heating time (sec) | 43 | 43 | 43 | 43 | 20 | 43 |
| | Step 2 | Heating temperature (° C.) | 100 | 100 | 100 | 100 | 100 | 100 |
| | | Heating time (sec) | 43 | 43 | 43 | 43 | 20 | 43 |
| | Value expressed by Formula (I) | | 9460 | 9460 | 9460 | 9460 | 4400 | 9460 |
| Evaluation | Volatile (%) | | 0.9 | 0.9 | 1.5 | 1.8 | 1.6 | 0.9 |
| | Resin flowability (%) | | 4 | 8 | 25 | >50 | 13 | 3 |
| | Batch | Heat resistance of oven | A | A | A | B | B | A |
| | press | Fillability | A | A | A | A | A | B |
| | method | Dk | 3.3 | 3.3 | 3.3 | 3.3 | 3.3 | 3.3 |
| | | Copper foil peel strength (kN/m) | 0.6 | 0.5 | 0.5 | 0.4 | 0.6 | 0.6 |
| | | CTE (ppm/° C.) | 13 | 13 | 13 | 13 | 13 | 13 |
| | Continuous | Glass transition temperature (° C.) | 200 | 190 | 180 | 170 | 200 | 200 |
| | press | Fillability | A | A | A | A | A | A |
| | method | Thickness accuracy | A | A | A | B | A | A |
| | | Dk | 3.3 | 3.3 | 3.3 | 3.3 | 3.3 | 3.3 |
| | | Copper foil peel strength (kN/m) | 0.6 | 0.5 | 0.5 | 0.4 | 0.6 | 0.6 |
| | | CTE (ppm/° C.) | 13 | 13 | 13 | 13 | 13 | 13 |

| | | | Examples | | | | |
|---|---|---|---|---|---|---|---|
| | | | 7 | 8 | 9 | 10 | 11 |
| Chemical | Modified polyphenylene ether compound | | 85 | 90 | 80 | 70 | 85 |
| makeup | Polybutadiene | | 15 | 10 | 20 | 30 | 15 |
| (parts by | Flame retardant 1 | | 12 | 12 | 12 | 12 | 12 |
| mass) | Flame retardant 2 | | 6 | 6 | 6 | 6 | 6 |
| | Inorganic filler | | 90 | 90 | 90 | 90 | |
| | Silane coupling agent | | 1 | 1 | 1 | 1 | 1 |
| | Hindered amine-based polymerization inhibitor | | 0.006 | 0.006 | 0.006 | 0.006 | 0.006 |
| | Composite particles 1 | | | | | | |
| | Composite particles 2 | | | | | | 90 |
| | Composite particles 3 | | | | | | |
| | Composite particles 4 | | | | | | |
| | Composite particles 5 | | | | | | |
| | Toluene | | 100 | 100 | 100 | 100 | 100 |
| Heating | Step 1 | Heating temperature (° C.) | 120 | 120 | 120 | 120 | 120 |
| step | | Heating time (sec) | 55 | 43 | 43 | 43 | 43 |
| | Step 2 | Heating temperature (° C.) | 100 | 100 | 100 | 100 | 100 |
| | | Heating time (sec) | 55 | 43 | 43 | 43 | 43 |

| | | | | | | |
|---|---|---|---|---|---|---|
| | Value expressed by Formula (I) | 12100 | 9460 | 9460 | 9460 | 9460 |
| Evaluation | Volatile (%) | 0.6 | 0.9 | 0.9 | 1.2 | 0.9 |
| | Resin flowability (%) | 3 | 4 | 5 | 9 | 16 |

| | | | | | | |
|---|---|---|---|---|---|---|
| Batch | Heat resistance of oven | A | A | A | A | A |
| press | Fillability | B | A | A | A | A |
| method | Dk | 3.3 | 3.3 | 3.3 | 3.2 | 3.0 |
| | Copper foil peel strength (kN/m) | 0.6 | 0.6 | 0.6 | 0.5 | 0.6 |
| | CTE (ppm/° C.) | 13 | 13 | 13 | 13 | 13 |
| Continuous | Glass transition temperature (° C.) | 200 | 200 | 200 | 190 | 200 |
| press | Fillability | A | A | A | A | A |
| method | Thickness accuracy | A | A | A | A | A |
| | Dk | 3.3 | 3.3 | 3.3 | 3.3 | 3.0 |
| | Copper foil peel strength (kN/m) | 0.6 | 0.6 | 0.6 | 0.5 | 0.6 |
| | CTE (ppm/° C.) | 13 | 13 | 13 | 13 | 13 |

TABLE 2

| | | | Examples | | | | | |
|---|---|---|---|---|---|---|---|---|
| | | | 12 | 13 | 14 | 15 | 16 | 17 |
| Chemical | Modified polyphenylene ether compound | | 85 | 85 | 85 | 85 | 85 | 85 |
| makeup | Polybutadiene | | 15 | 15 | 15 | 15 | 15 | 15 |
| (parts by | Flame retardant 1 | | 12 | 12 | 12 | 12 | 12 | 12 |
| mass) | Flame retardant 2 | | 6 | 6 | 6 | 6 | 6 | 6 |
| | Inorganic filler | | | | | | | |
| | Silane coupling agent | | 1 | 1 | 1 | 1 | 1 | 1 |
| | Hindered amine-based polymerization inhibitor | | 0.006 | | | | | |
| | Composite particles 1 | | 90 | | | | | |
| | Composite particles 2 | | | 90 | 10 | 200 | | 250 |
| | Composite particles 3 | | | | | | 90 | |
| | Composite particles 4 | | | | | | | |
| | Composite particles 5 | | | | | | | |
| | Toluene | | 100 | 100 | 100 | 100 | 100 | 100 |
| Heating | Step 1 | Heating temperature (° C.) | 120 | 120 | 120 | 120 | 120 | 120 |
| step | | Heating time (sec) | 43 | 43 | 43 | 43 | 43 | 43 |
| | Step 2 | Heating temperature (° C.) | 100 | 100 | 100 | 100 | 100 | 100 |
| | | Heating time (sec) | 43 | 43 | 43 | 43 | 43 | 43 |
| | Value expressed by Formula (I) | | 9460 | 9460 | 9460 | 9460 | 9460 | 9460 |
| Evaluation | Volatile (%) | | 0.9 | 0.9 | 0.9 | 0.9 | 0.9 | 0.9 |
| | Resin flowability (%) | | 16 | 8 | 4 | 18 | 6 | 22 |
| | Batch | Heat resistance of oven | A | A | A | A | A | A |
| | press | Fillability | A | A | A | A | A | A |
| | method | Dk | 3.0 | 3.0 | 3.1 | 2.8 | 3.1 | 2.7 |
| | | Copper foil peel strength (kN/m) | 0.2 | 0.6 | 0.9 | 0.5 | 0.6 | 0.1 |
| | | CTE (ppm/° C.) | 13 | 13 | 15 | 11 | 14 | 10 |
| | Continuous | Glass transition temperature (° C.) | 200 | 200 | 200 | 200 | 200 | 200 |
| | press | Fillability | A | A | A | A | A | A |
| | method | Thickness accuracy | A | A | A | A | A | A |
| | | Dk | 3.0 | 3.0 | 3.1 | 2.8 | 3.1 | 2.7 |
| | | Copper foil peel strength (kN/m) | 0.2 | 0.6 | 0.9 | 0.5 | 0.6 | 0.1 |
| | | CTE (ppm/° C.) | 13 | 13 | 15 | 11 | 14 | 10 |

| | | | | | Comparative | | |
|---|---|---|---|---|---|---|---|
| | | | Examples | | Examples | | |
| | | | 18 | 19 | 1 | 2 | 3 |
| Chemical | Modified polyphenylene ether compound | | 85 | 90 | 80 | 70 | 85 |
| makeup | Polybutadiene | | 15 | 15 | 15 | 15 | 15 |
| (parts by | Flame retardant 1 | | 12 | 12 | 12 | 12 | 12 |
| mass) | Flame retardant 2 | | 6 | 6 | 6 | 6 | 6 |
| | Inorganic filler | | | | 90 | 90 | |
| | Silane coupling agent | | 1 | 1 | 1 | 1 | 1 |
| | Hindered amine-based polymerization inhibitor | | | | | | |
| | Composite particles 1 | | | | | | |
| | Composite particles 2 | | | | | | |
| | Composite particles 3 | | | | | | |
| | Composite particles 4 | | 90 | | | | |
| | Composite particles 5 | | | 90 | | | |
| | Toluene | | 100 | 100 | 100 | 100 | 100 |
| Heating | Step 1 | Heating temperature (° C.) | 120 | 120 | 120 | 120 | 120 |
| step | | Heating time (sec) | 43 | 43 | 30 | 20 | 43 |
| | Step 2 | Heating temperature (° C.) | 100 | 100 | 120 | 120 | 100 |
| | | Heating time (sec) | 43 | 43 | 30 | 20 | 43 |

| | | | | | | |
|---|---|---|---|---|---|---|
| | Value expressed by Formula (I) | 9460 | 9460 | 7200 | 4800 | 9460 |
| Evaluation | Volatile (%) | 0.9 | 0.9 | 0.9 | 1.6 | 0.9 |
| | Resin flowability (%) | 4 | 20 | 0 | 9 | 3 |

| | | | | | | |
|---|---|---|---|---|---|---|
| Batch | Heat resistance of oven | A | A | C | C | A |
| press | Fillability | A | B | C | A | A |
| method | Dk | 3.2 | 2.8 | 3.3 | 3.3 | 3.2 |
| | Copper foil peel strength (kN/m) | 0.6 | 0.6 | 0.6 | 0.6 | 1.0 |
| | CTE (ppm/° C.) | 18 | 10 | 13 | 13 | 20 |
| Continuous | Glass transition temperature (° C.) | 200 | 200 | 200 | 200 | 200 |
| press | Fillability | A | B | A | A | A |
| method | Thickness accuracy | A | A | A | A | A |
| | Dk | 3.2 | 2.8 | 3.3 | 3.3 | 3.2 |
| | Copper foil peel strength (kN/m) | 0.6 | 0.6 | 0.6 | 0.6 | 1.0 |
| | CTE (ppm/° C.) | 18 | 10 | 13 | 13 | 20 |

In a first comparative example in which no hindered amine-based polymerization inhibitor was used, the heat resistance of oven and the fillability by the batch press method were graded bad. In a second comparative example in which the same composition was used but the heating condition at the time of forming a prepreg was changed, the fillability grade improved but the volatile evaluation and heat resistance deteriorated. In a third comparative example containing no hindered amine-based polymerization inhibitor, inorganic filler, or composite particles, the peel strength of copper foil was high, but the coefficient of linear expansion was also high.

In contrast, in first to fourth examples in which the hindered amine-based polymerization inhibitor was used and the condition expressed by the mathematical formula (I) was satisfied, the heat resistance and fillability grades were both good and the glass transition temperature was also sufficiently high. The glass transition temperature tended to increase as the content of the hindered amine-based polymerization inhibitor decreased.

In a fifth example in which the same composition as in the first example was adopted, the heating condition at the time of forming a prepreg was changed, and the condition expressed by the mathematical formula (I) was not satisfied, the resin flowability and the volatile evaluation grades improved but the heat resistance and fillability grades were sufficiently good and the glass transition temperature was sufficiently high, compared to the first example.

In a sixth example in which the content of the hindered amine-based polymerization inhibitor was decreased compared to the first example, the grade of the fillability by the batch press method declined somewhat but was still better than in the first comparative example.

In a seventh example in which the same composition as in the first example was adopted, the heating condition at the time of forming a prepreg was changed, and the condition expressed by the mathematical formula (I) was not satisfied, the grade of the fillability by the batch press method declined somewhat but was still better than in the first comparative example.

In eighth to tenth examples, the component ratio between polyphenylene ether and polybutadiene was changed from the one of the first example but the heat resistance and fillability grades were good and the glass transition temperature was sufficiently high.

In eleventh to nineteenth examples, no inorganic filler was used but composite particles were used. In these eleventh to nineteenth examples, the heat resistance and fillability grades were also good and the glass transition temperature was sufficiently high.

Particularly, in the eleventh and twelfth examples in which the composite particles and the hindered amine-based polymerization inhibitor were used in combination, the resin flowability of the prepreg could be increased appropriately. Furthermore, in the eleventh example in which silica particles of the composite particles were treated with phenylamino, a high copper foil peel strength was achieved.

Furthermore, among the thirteenth to nineteenth examples, each containing composite particles but containing no hindered amine-based polymerization inhibitor, in the thirteenth to fifteenth examples and the seventeenth example in which the type of the composite particles was not changed but the content thereof was changed, the larger the content of the composite particles was, the lower the relative dielectric constant was, but the copper foil peel strength tended to decrease. Meanwhile, in the thirteenth, sixteenth, eighteenth, and nineteenth examples in which the particle size of the core of the composite particles was changed with the content of the composite particles unchanged, the larger the particle size of the core was, the more easily the coefficient of linear expansion could be reduced and good resin flowability was obtained.

1. A resin composition containing:
a modified polyphenylene ether compound (A) having, at one terminal, a group with an unsaturated double bond;
a cross-linking agent (B) having a carbon-carbon double bond;
a hindered amine-based polymerization inhibitor (C); and
a solvent (D).

2. The resin composition of claim 1, wherein
percentage of the hindered amine-based polymerization inhibitor (C) falls within a range from 0.001% by mass to 0.048% by mass with respect to total content of the compound (A) and the cross-linking agent (B).

3. The resin composition of claim 1, further containing composite particles (I), each of the composite particles (I) having a core containing a fluororesin and a shell containing a silicon oxide that coats the core.

4. The resin composition of claim 3, wherein
the silicon oxide is treated with phenylamino.

5. A resin composition containing:
a modified polyphenylene ether compound (A) having, at one terminal, a group with an unsaturated double bond;
a cross-linking agent (B) having a carbon-carbon double bond;
composite particles (I), each of the composite particles (I) having a core containing a fluororesin and a shell containing a silicon oxide that coats the core; and
a solvent (D),
the silicon oxide being treated with phenylamino.

6. The resin composition of claim 3, wherein
content of the composite particles (I) falls within a range from 10 parts by weight to 200 parts by weight with respect to 100 parts by weight in total of the compound (A) and the cross-linking agent (B).

7. The resin composition of claim 3, wherein
the core of the composite particles (I) has a mean particle size falling within a range from 0.1 μm to 20 μm.

8. The resin composition of claim 1, further containing a flame retardant (E).

9. The resin composition of claim 1, further containing an inorganic filler (F).

10. The resin composition claim 1, further containing a silane coupling agent (G).

11. The resin composition of claim 1, wherein
a cured product of the resin composition has a glass transition temperature equal to or higher than 180° C.

12. A prepreg comprising a dried or semi-cured product of the resin composition of claim 1.

13. The prepreg of claim 12, wherein
the prepreg has a volatile content less than 1.5% by volatile evaluation.

14. The prepreg of claim 12, wherein
the prepreg has a resin flowability evaluated to fall within a range from 4% to 25%.

15. A method for manufacturing a prepreg, the method comprising:
impregnating a base material with the resin composition of claim 1; and
heating the resin composition after the impregnating,
the heating satisfying a heating condition expressed by the following mathematical formula (I):
$$4500 ≦ {\sum }_{n = 1}^{i} ( {Tp}_{n} + {Tm}_{n} ) ≦ 10000 \qquad ( 1 )$$
where i indicates a numerical number of process steps having respectively different heating temperatures and included in the heating, Tpₙ indicates a heating temperature (° C.) in an n^{th} process step out of the i process steps, and Tmₙ indicates a heating time (sec) in the n^{th} process step out of the i process steps.

16. A laminate comprising an insulating layer containing a cured product of the resin composition of claim 1.

17. A printed wiring board comprising an insulating layer containing a cured product of the resin composition of claim 1.

18. The printed wiring board of claim 17, wherein
the printed wiring board is a package board.

19. The resin composition of claim 5, wherein
content of the composite particles (I) falls within a range from 10 parts by weight to 200 parts by weight with respect to 100 parts by weight in total of the compound (A) and the cross-linking agent (B).

20. The resin composition of claim 5, wherein
the core of the composite particles (I) has a mean particle size falling within a range from 0.1 μm to 20 μm.

21. The resin composition of claim 5, further containing a flame retardant (E).

22. The resin composition of claim 5, further containing an inorganic filler (F).

23. The resin composition claim 5, further containing a silane coupling agent (G).

24. The resin composition of claim 5, wherein
a cured product of the resin composition has a glass transition temperature equal to or higher than 180° C.

25. A prepreg comprising a dried or semi-cured product of the resin composition of claim 5.

26. The prepreg of claim 25, wherein
the prepreg has a volatile content less than 1.5% by volatile evaluation.

27. The prepreg of claim 25, wherein
the prepreg has a resin flowability evaluated to fall within a range from 4% to 25%.

28. A method for manufacturing a prepreg, the method comprising:
impregnating a base material with the resin composition of claim 5; and
heating the resin composition after the impregnating,
the heating satisfying a heating condition expressed by the following mathematical formula (I):
$$4500 ≦ {\sum }_{n = 1}^{i} ( {Tp}_{n} + {Tm}_{n} ) ≦ 10000 \qquad ( 1 )$$
where i indicates a numerical number of process steps having respectively different heating temperatures and included in the heating, Tpₙ indicates a heating temperature (° C.) in an n^{th} process step out of the i process steps, and Tmₙ indicates a heating time (sec) in the n^{th} process step out of the i process steps.

29. A laminate comprising an insulating layer containing a cured product of the resin composition of claim 5.

30. A printed wiring board comprising an insulating layer containing a cured product of the resin composition of claim 5.

31. The printed wiring board of claim 30, wherein
the printed wiring board is a package board.
